(19) United States
(12) Patent Application Publication
(10) Pub. No.: US 2007/0086172 A1
(43) Pub. Date: Apr. 19, 2007

(54) DO IT YOURSELF SERVER MODULES

(75) Inventors: Hsiu-Chang Lai, Tu-Cheng,Taipei Hsien (TW); Ke Sun, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,791

(22) Filed: Sep. 28, 2006

(30) Foreign Application Priority Data
Oct. 17, 2005 (CN) 200510100549.9

(51) Int. Cl. H05K 7/16

(52) U.S. Cl. 361/727; 361/796

(57) ABSTRACT

An exemplary server includes a rack, a first module, a second module, and a third module. The first module is slidably attached to an end of the rack in a first direction. The second module is slidably attached to another end of the rack in a second direction opposite to the first direction. The third module is slidably attached to the rack in a third direction perpendicular to the first direction. The first module and the second module are electronically connected to the third module.

### CROSS-REFERENCES TO RELATED APPLICATION

Relevant subject matter is disclosed in the co pending U.S. patent application Ser. No. 11/308,743, filed on Apr. 28, 2006, and entitled “DO IT YOURSELF SERVER MODULES”, which is assigned to the same assignee with this patent application.

### FIELD OF THE INVENTION

The present invention relates to a server, and particularly to server modules suitable for do it yourself (DIY) server assembly and repair.

### DESCRIPTION OF RELATED ART

Conventionally, a server includes a base dock, and an upper lid. The base dock has an upper beam bridging two opposite ends thereof. One end of the base dock is for mounting a plurality of data processing components, such as circuit boards, hard disk drives, and so on. The other end of the base dock is for mounting a plurality of auxiliary components, such as power supplies, fans, network switches, and so on. The upper lid is mounted to the base dock to enclose the data processing components and the auxiliary components. Sometimes, the data processing components or the auxiliary components may wear out. Worn out components should be repaired. However, some worn out components cannot be repaired. Thus, a new server should be bought to replace the above-mentioned server, which would be expensive.

Do it yourself (DIY) computer assembly is currently popular because DIY computer modules can be assembled to form a computer which is according to a user's taste. If some component of a module should wear out and cannot be repaired, the user need only replace that module, which is much less expensive than replacing the whole computer. Additionally, people enjoy a sense of achievement having assembled a computer. This option, however, is not available yet with servers for people who enjoy DIY projects.

What is desired, therefore, is server composed of modules suitable for people who would enjoy to do it for themselves.

### SUMMARY OF THE INVENTION

An exemplary server includes a rack, a first module, a second module, and a third module. The first module is slidably attached to an end of the rack in a first direction. The second module is slidably attached to another end of the rack in a second direction opposite to the first direction. The third module is slidably attached to the rack in a third direction perpendicular to the first direction. The first module and the second module are electronically connected to the third module.

Other advantages and novel features will become more apparent from the following detailed description when taken in conjunction with the accompanying drawings, in which:

### BRIEF DESCRIPTION OF THE DRAWINGS

FIG. 1 is an isometric view of a server in accordance with a preferred embodiment of the present invention; and

FIGS. 2 and 3 are assembled views of FIG. 1, but showing different states of the sever.

### DETAILED DESCRIPTION OF THE INVENTION

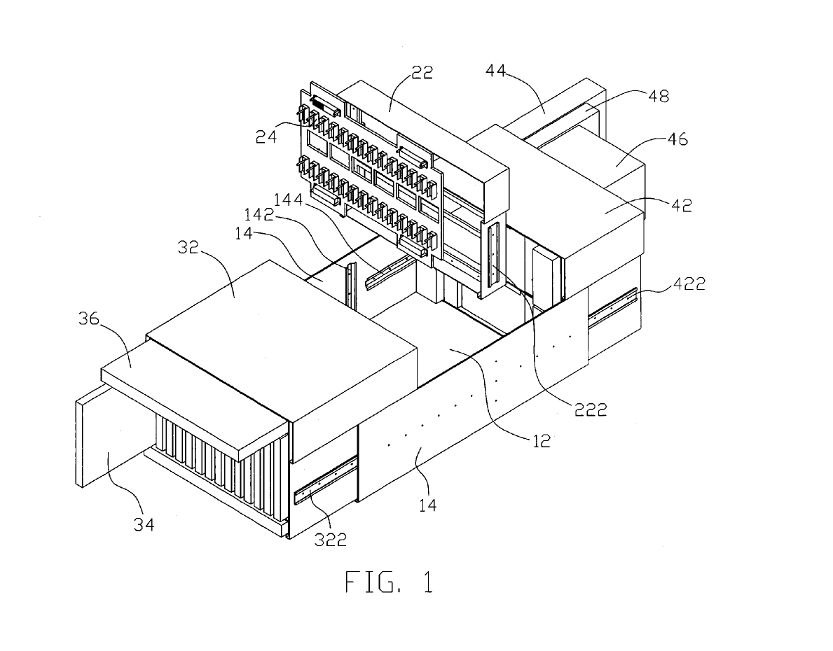

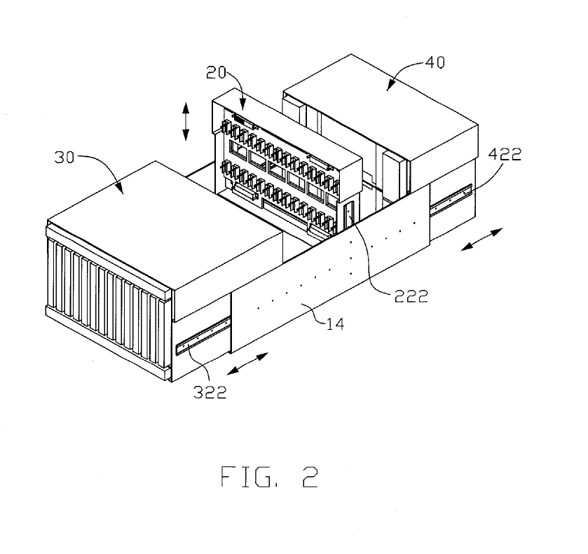

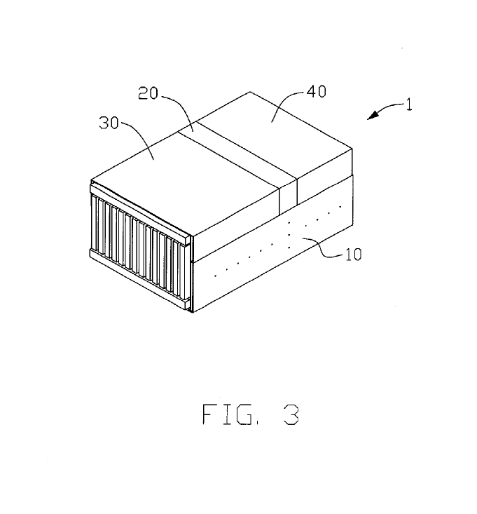

Referring to FIGS. 1 to 3, a server in accordance with a preferred embodiment of the present invention includes a rack 10, a front module 30, a back module 40, and a middle module 20.

The rack 10 includes a bottom plate 12, and a pair of side plates 14, cooperatively defining a space to receive the front module 30, the middle module 20, and the back module 40 therein. Each of the side plates 14 includes a pair of horizontal railways 144, and a vertical railway 142, attached to interior surfaces thereof. The horizontal railways 144 are arranged in alignment with each other. The vertical railway 142 is disposed between the horizontal railways 144. The railways 142 and 144 can be directly formed at the side plates 14 of the rack 10. The horizontal railways 144 can also be arranged offset from each other, instead of being arranged in a line.

The front module 30 includes a bracket 32. A plurality of data processing components, such as circuit boards 34, hard disk drives 36, and so on, is mountable to the bracket 32. Two rails 322 are horizontally mounted to opposite sides of the bracket 32 respectively.

The back module 40 includes a bracket 42. A plurality of auxiliary components, such as power supplies 46, fans 48, network switches 44, and so on, is mountable to the bracket 42. Two rails 422 are horizontally mounted to opposite sides of the bracket 42 respectively.

The auxiliary components of the back module 40 serve the data processing components of the front module 30 via the middle module 20. The middle module 20 includes a bracket 22. A plurality of connecting members 24 is mountable to the bracket 22. Two rails 222 are vertically mounted to opposite sides of the bracket 22 respectively.

In assembly, the front module 30 and the back module 40 are slidably and horizontally placed into the rack 10 from opposite ends toward each other, with the rails 322 and 422 sliding along the railways 144 of the rack 10. The middle module 20 is attached vertically to the rack 10, with the rails 222 sliding along the railways 142 of the rack 10.

The rails 322, 422, 322 can be directly formed at the side plates of bracket 32, 42, 22, respectively. The rails 142 and 144 of the rack 10 can be designed according to other suitable structures.

The server can be broken down into separate modules for convenient packing and transportation. Additionally, the modular design allows convenient repair, replacement, or upgrading of a part of a server rather than the great expense of replacing the whole server. Moreover, users can select the modules to assemble a server according to their individual taste and needs.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment.

What is claimed is:

1. A server comprising:
a rack;
a first module slidably attached to an end of the rack in a first direction;
a second module slidably attached to another end of the rack in a second direction opposite to the first direction; and
a third module slidably attached to the rack in a third direction perpendicular to the first direction, the first module and the second module electronically connected to the third module.

2. The server as claimed in claim 1, wherein the rack comprises a pair of side plates, each of the side plates includes a pair of parallel first railways, and a second railway perpendicular to the first railways.

3. The server as claimed in claim 2, wherein the first module comprises a plurality of data processing components, and a first bracket able to receive the data processing components mounted therein.

4. The server as claimed in claim 2, wherein the first bracket comprises two rails formed on opposite sides thereof respectively to engage with one of the pair of the first railways.

5. The server as claimed in claim 4, wherein the second module comprises a plurality of auxiliary components to serve the data processing components, and a second bracket able to receive the auxiliary components mounted therein.

6. The server as claimed in claim 2, wherein the second bracket comprises two rails formed on opposite sides thereof respectively to engage with one of the pair of the first railways.

7. The server as claimed in claim 2, wherein the third module comprises a plurality of connecting components to communicate the data processing components of the first module with the auxiliary components of the second module, and a third bracket able to receive the connecting components mounted therein.

8. The server as claimed in claim 7, wherein the third bracket comprises two rails formed on opposite sides thereof respectively to engage with the second railways of the rack.

9. A server comprising:
a rack; and
a plurality of modules slidably mounted into the rack in at least two angular directions.

10. The server as claimed in claim 9, wherein the plurality of modules comprise a front module slidably mounted into the rack in a first direction, a back module slidably mounted into the rack in a second direction parallel to the first direction, and a middle module slidably mounted into the rack in a third direction perpendicular to the first direction.

11. The server as claimed in claim 10, wherein the rack comprises a pair of side plates, each of the side plates comprises a pair of first railways in alignment with each other, and a second railway perpendicular to the first railways, the second railway is disposed between the first railways.

12. The server as claimed in claim 11, wherein the front module comprises a plurality of data processing components, and a bracket able to receive the data processing components mounted therein, the bracket comprises two rails formed on opposite sides thereof respectively slidably engaging with one of the pair of the first railways.

13. The server as claimed in claim 12, wherein the back module comprises a plurality of auxiliary components to serve the data processing components, and a bracket able to receive the auxiliary components mounted therein, the bracket comprises two rails formed on opposite sides thereof respectively engaging with another of the pair of the first railways.

14. The server as claimed in claim 11, wherein the middle module comprises a plurality of connecting components to communicate the data processing components of the first module with the auxiliary components of the second module, and a bracket able to receive the connecting components mounted therein, the bracket comprises two rails formed on opposite sides thereof respectively engaging with the second railway.

15. A server comprising:
a rack comprising a pair of parallel side plates, each of the side plates comprising a pair of horizontal railways, and a vertical railway arranged between the horizontal railways;
a front module and a back module slidably mounted into the rack from opposite ends of the rack along the horizontal rails; and
a middle module slidably mounted into the rack along the vertical rails.
